(19) United States
(12) Patent Application Publication
(10) Pub. No.: US 2007/0099360 A1
(43) Pub. Date: May 3, 2007

(54) INTEGRATED CIRCUITS HAVING STRAINED CHANNEL FIELD EFFECT TRANSISTORS AND METHODS OF MAKING

(75) Inventors: Yong Meng Lee, Singapore (SG); Haining S. Yang, Wappingers Falls, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/163,916

(22) Filed: Nov. 3, 2005

(51) Int. Cl. H01L 21/8234; H01L 21/8238; H01L 21/336; H01L 29/94; H01L 27/108; H01L 29/76; H01L 31/119

(52) U.S. Cl. 438/197; 438/199; 257/310

(57) ABSTRACT

An integrated circuit is provided that includes a substrate, a p-type field effect transistor, a compressive nitride layer, n-type field effect transistor, a tensile nitride layer, and a mask. The compressive nitride layer induces a first compressive stress in a channel region of the p-type field effect transistor. The tensile nitride layer induces a tensile stress in a channel region of the n-type field effect transistor. The mask is defined over an exposed gate conductor of the n-type field effect transistor. The p-type field effect transistor includes a gate conductor having a metal silicide layer with a volume sufficient to induce a second compressive stress in the channel region of the p-type field effect transistor.

### BACKGROUND OF THE INVENTION

The present invention relates to the fabrication of semiconductor integrated circuits. More particularly, the present invention relates to strained channel field effect transistors and methods of making.

Both theoretical and empirical studies have demonstrated that carrier mobility in complementary metal oxide semiconductor (CMOS) transistors can be greatly increased when a stress of sufficient magnitude is applied to the conduction channel of a transistor to create a strain therein. Stress is defined as force per unit area. Strain is a dimensionless quantity defined as the unit change, for example a percentage change, in a particular dimension of an item, in relation to its initial dimension of that item. An example of strain is the change in length versus the original length, when a force is applied in the direction of that dimension of the item: for example in the direction of its length. Strain can be either tensile or compressive.

In p-type field effect transistors (PFET), the application of a compressive longitudinal stress on the conduction channel, i.e. in the direction of the length of the conduction channel, creates a strain in the conduction channel, which is known to increase the drive current of the PFET. However, if the same compressive stress is applied to the conduction channel of an n-type field effect transistor (NFET), its drive current decreases. Conversely, when a tensile stress is applied to the conduction channel of the NFET, the drive current of the NFET increases.

Accordingly, it has been proposed to increase the performance of an NFET by applying a tensile longitudinal stress to the conduction channel of the NFET, while increasing the performance of a PFET by applying a compressive longitudinal stress to its conduction channel. Several ways have been proposed to impart different kinds of stresses to different regions of a wafer that house the NFET and PFET. In one example, mechanical stress is manipulated by altering the materials in shallow trench isolation regions (STIs) disposed adjacent to the conduction channels of field effect transistors (FETs) to apply a desired stress thereto. Other proposals have centered on modulating intrinsic stresses present in spacer features. Yet other proposals have focused on introducing etch-stop layers such as those that include silicon nitride (Si₃N₄). However, there are drawbacks with each of these approaches. For instance, these techniques can lead to significant processing costs.

Therefore, there is a need for a process that employs stress to achieve variations in carrier mobility.

### SUMMARY OF THE INVENTION

It is an object of the present disclosure to increase compressive stress in a PFET channel region, thereby changing an electrical characteristic of the channel region.

These and other objects and advantages of the present invention are provided by an integrated circuit. The integrated circuit includes a substrate, a p-type field effect transistor, a compressive nitride layer, n-type field effect transistor, a tensile nitride layer, and a hard mask. The compressive nitride layer induces a first compressive stress in a channel region of the p-type field effect transistor. The tensile nitride layer induces a tensile stress in a channel region of the n-type field effect transistor. The hard mask is defined over an exposed gate conductor of the n-type field effect transistor.

In some embodiments, the p-type field effect transistor includes a gate conductor having a metal silicide layer with a volume sufficient to induce a second compressive stress in the channel region of the p-type field effect transistor.

An integrated circuit is also provided that includes a substrate, a p-type field effect transistor, a channel region, first and second spacers, and a compressive nitride layer. The substrate has a source region and a drain region. The p-type field effect transistor has a gate conductor disposed on the substrate, where the gate conductor includes a gate dielectric, a polysilicon layer, and a metal silicide layer. The compressive nitride layer is defined over the gate conductor and the spacers. The compressive nitride layer induces a first compressive stress in the channel region. The metal silicide layer has a volume sufficient to induce a second compressive stress in the channel region.

A method of manufacturing an integrated circuit is also provided. The method includes laying a tensile stress nitride layer over an n-type field effect transistor to induce a tensile stress on the n-type field effect transistor, laying a compressive stress nitride layer over a p-type field effect transistor to induce a first compressive stress on the p-type field effect transistor, removing at least part of the tensile and compressive nitride layers to expose a gate conductor of the n-type field effect transistor and the p-type field effect transistor, applying a mask over the gate conductor of the n-type field effect transistor, and inducing a second compressive stress on the p-type field effect transistor.

### BRIEF DESCRIPTION OF THE DRAWINGS

FIG. 1 is a top view of a first embodiment of an integrated circuit after a dual nitride process according to the present invention;

FIG. 2 is a sectional view of the integrated circuit of FIG. 1, taken along lines 2-2;

FIG. 3 is a sectional view of the integrated circuit of FIG. 1, taken along lines 3-3;

FIG. 4 is a sectional view of the integrated circuit of FIG. 1, taken along lines 4-4;

FIG. 5 is a sectional view of the integrated circuit of FIG. 4, after application of an oxide layer;

FIG. 6 is a sectional view of the integrated circuit of FIG. 5, after a planarization step;

FIG. 7 is a sectional view of the integrated circuit of FIG. 6, after a masking step;

FIG. 8 is a sectional view of the integrated circuit of FIG. 7, after a metal film deposition step;

FIG. 9 is a sectional view of the integrated circuit of FIG. 8, after a reactive thermal anneal step;

FIG. 10 is a sectional view of the integrated circuit of FIG. 9, after a full silicization step;

FIG. 11 is a sectional view of the integrated circuit of FIG. 10 after an oxide deposition step and a contact formation step;

FIG. 12 is a top view of a second embodiment of an integrated circuit after a dual nitride process according to the invention;

FIG. 13 is a side view of the second embodiment of FIG. 12; and

FIG. 14 is a block diagram of an exemplary method of manufacturing an integrated circuit according to the present invention.

### DESCRIPTION OF THE INVENTION

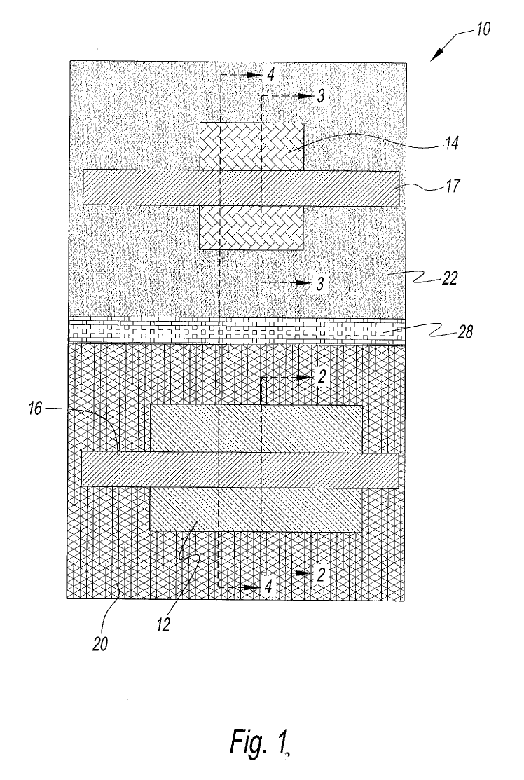

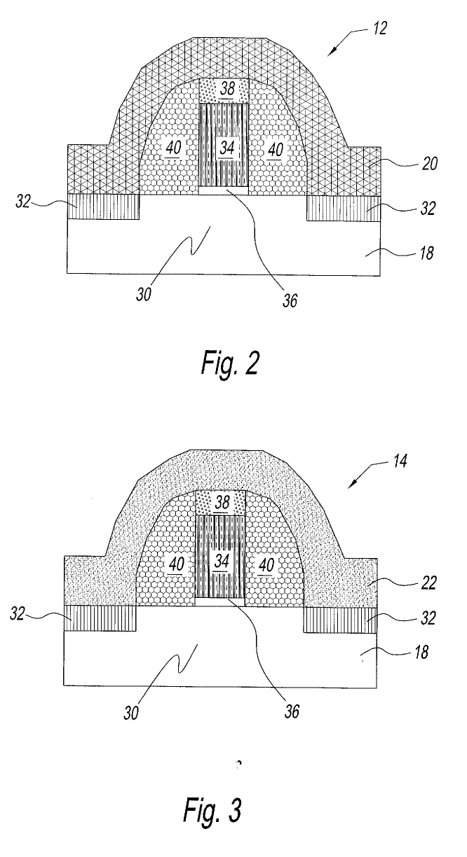

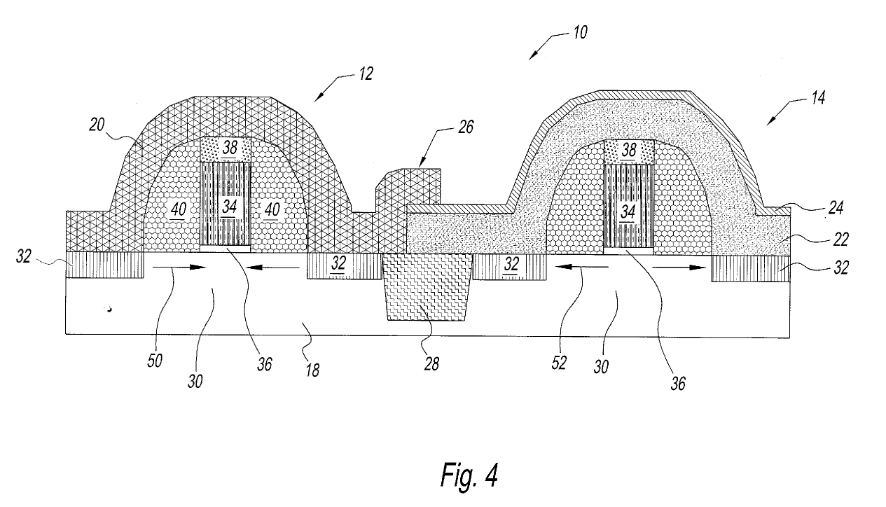

Referring to the drawings and, in particular, to FIGS. 1 through 4, there is shown an integrated circuit according to the present invention generally referred to by reference numeral 10. Integrated circuit 10 includes a p-type field effect transistor (PFET) 12, an n-type field effect transistor (NFET) 14, a PFET gate conductor 16, an NFET gate conductor 17, and a substrate 18. Substrate 18 may either be a bulk substrate or may preferably be a semiconductor-on-insulator or silicon-on-insulator (SOI) substrate in which a relatively thin layer of a semiconductor is formed over an insulating layer.

Integrated circuit 10 takes advantage of a dual stress liner (DSL) process that not only stretches the silicon lattice in NFET 14, but also compresses the lattice in PFET 12, by applying tensile stress nitride and compressive nitride to N and PFET, respectively.

For example, integrated circuit 10 includes a compressive stress nitride layer 20 over PFET 12 and a tensile stress nitride layer 22 over NFET 14. Nitride layers 20, 22 preferably comprise Si₃N₄ and can be deposited using known processes. Nitride layers 20, 22 are configured to maintain PFET 12 and NFET 14, respectively, in the stressed condition induced by the aforementioned DSL process.

Integrated circuit 10 also includes an etch stop layer 24 over tensile stress nitride layer 22. Etch stop layer 24 (preferably SiO2) also can be deposited using known processes.

During manufacture, tensile stress nitride layer 22 is first deposited over NFET 14. Next, etch stop layer 24 is deposited over tensile stress nitride layer 22. Tensile nitride and etch stop layer is then etched from PFET. Finally, compressive stress nitride layer 20 is deposited over PFET 12 and NFET region. Compressive nitride is then removed from NFET region using photo resist mask, an overlap region 26 is formed between NFET and PFET region. In an alternative process flow, compressive nitride can be deposited before the tensile nitride. Integrated circuit 10 also includes a shallow trench isolation region (STI) 28 defined in substrate 18 between PFET 12 and NFET 14.

PFET 12 and NFET 14 each include a channel region 30 and source/drain regions 32. Channel region 30 is defined under PFET gate conductor 16 and NFET gate conductor 17, while source/drain regions 32 are defined in the substrate 18 adjacent the channel region.

PFET Gate conductor 16 and NFET gate conductor 17 has a polysilicon layer 34, a gate dielectric 36, and, in some embodiments, an upper layer 38. Polysilicon layer 34 is in contact with upper layer 38 and gate dielectric 36. Gate dielectric 36 is preferably a layer of silicon dioxide on substrate 18.

Polysilicon layer 34 is preferably doped to a concentration of about 10¹⁹ cm⁻³. Polysilicon layer 34 includes a p-type dopant in PFET 12, while the polysilicon layer includes an n-type dopant In NFET 14.

Upper layer 38 is preferably a low-resistance portion disposed above polysilicon layer 34. Upper layer 38 has much less resistance than the polysilicon layer 34, and preferably includes a metal, a silicide of a metal, or both. In a preferred embodiment, the upper layer 38 includes a silicide formed by a self-aligned process (a “salicide”), being a silicide of any suitable metal including, but not limited to, tungsten, titanium, cobalt, nickel, and any combinations thereof.

Source/drain regions 32 are spaced from channel regions 30 by spacers 40. Spacers 40 are preferably formed of silicon nitride, although the spacers can be formed of silicon dioxide or a combination of layers of silicon nitride and silicon dioxide.

In this manner, integrated circuit 10 having compressive stress nitride layer 20 induces a first compressive stress 50 in channel region 30 of PFET 12 to improve hole mobility. Conversely, integrated circuit 10 having tensile stress nitride layer 22 induces a tensile stress 52 in channel region 30 of NFET 14. The compressive and tensile stresses 50, 52 can be uni-axial, bi-axial, multi-axial, or any combinations thereof.

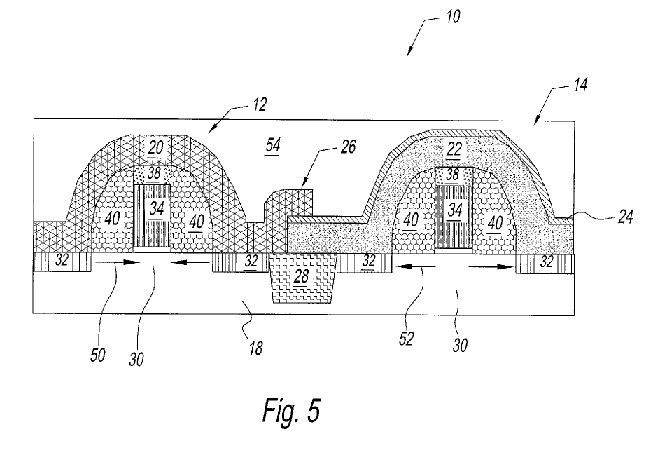

Referring now to FIG. 5, integrated circuit 10 includes an oxide layer 54 overlaying both etch stop layer 24 and compressive stress nitride layer 20. Oxide layer 54 preferably comprises an oxide such as silicon dioxide.

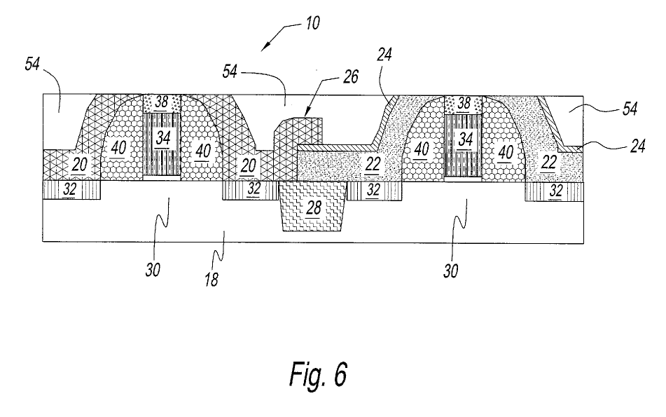

As shown in FIG. 6, integrated circuit 10 is then exposed to a planarization process. The planarization process removes oxide layer 54 and compressive stress nitride layer 20 from gate conductor 16 at PFET 12. In addition, the planarization process removes oxide layer 54, etch stop layer 24, and tensile stress nitride layer 22 from gate conductor 16 at NFET 14. For example, integrated circuit 10 is exposed to a process such as chemical-mechanical polishing (CMP), reactive ion etching (RIE), or any combinations thereof. In this manner, integrated circuit 10 is planarized until upper layer 38 of gate conductor 16 is exposed.

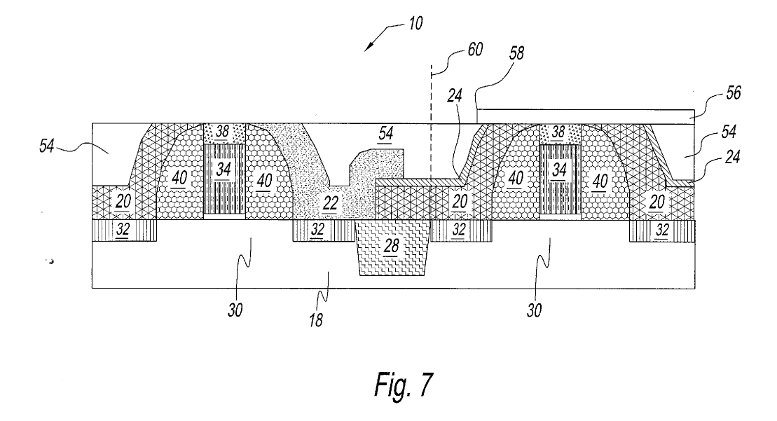

As shown in FIG. 7, integrated circuit 10 is then exposed to a masking process. The masking process deposits a mask 56 over NFET 14. Specifically, mask 56 is deposited to cover at least upper layer 38 of gate conductor 16 at NFET 14. Preferably, mask 56 has an edge 58 that terminates off-center from a plane 60 defined through an edge 62 of STI 28. In this manner, a contact that lands on a gate between NFET and PFET will land on a thick silicide region. Mask 56 can comprise a material such as oxide or nitride.

Advantageously, integrated circuit 10 having mask 56 is adapted to further increase the compressive stress induced in channel region 30 of PFET 12 without effecting the tensile stress induced in channel region 30 of NFET 14. Generally, mask 56 allows polysilicon layer 34 of PFET 12 to be exposed to further compressive stress inducing steps, while shielding the polysilicon layer of NFET 14 from these steps.

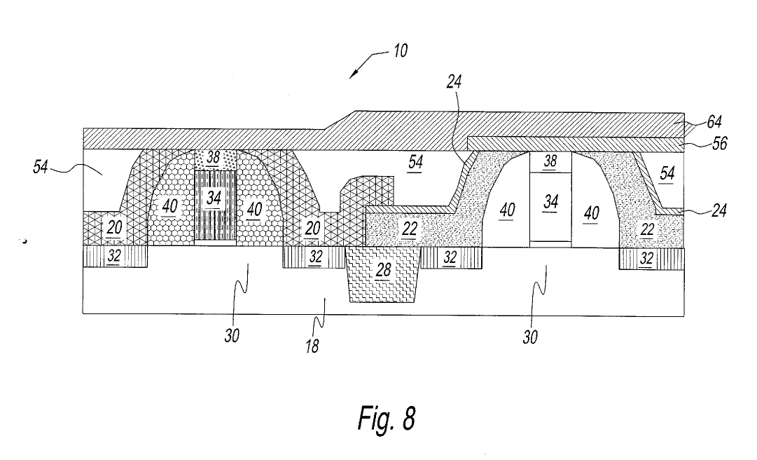

As shown in FIG. 8, integrated circuit 10 then exposed to a metal film deposition step. Here, a metal film 64 such as nickel or cobalt is deposited over mask 56 and upper layer 38 of PFET gate conductor 16 at PFET 12 and NFET gate conductor 17 at NFET 14.

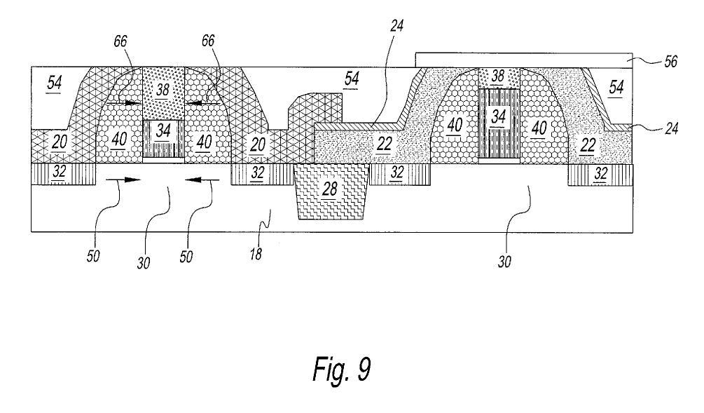

Next, integrated circuit 10 is then exposed to a reactive thermal anneal (RTA) step. The RTA step exposes integrated circuit 10 to heat sufficient to react metal film 64 with gate conductor 16 at PFET 12 to form additional metal silicide. Specifically, the reaction of metal film 64 with upper layer 38 (e.g., metal silicide) and polysilicon layer 34 converts polysilicon layer 34 into metal silicide, which decreases the volume of polysilicon layer 34 and increases the volume of upper layer 38 as shown in FIG. 9.

The reduction in volume of polysilicon layer 34 pulls nitride layer 20 inward and, thus, induces a second compressive stress 66 on channel region 30 of PFET 12 through spacers 40. The stress in the metal silicide is tensile and is between 1.0 to 1.5 GPa. The compressive stress induced in the channel is in general a fraction of this amount. As such, upper layer 38 (e.g., metal silicide) of PFET 12 has a volume sufficient to induce second compressive stress 66 in channel region 30.

Advantageously, the overall compressive stress induced on channel region 30 of PFET 12 is equal to the net of first compressive stress 50 and second compressive stress 66. In this manner, the overall compressive stress on channel region 30 of PFET 12 can be increased over those PFETS having only first compressive stress 50.

It should be noted that mask 56 at NFET 14 prevents the RTA step from causing a reaction between polysilicon layer 34 and metal film 64. In this manner, the overall compressive stress on channel region 30 of PFET 12 can be increased without effecting the tensile stress 52 induced on channel region 30 of NFET 14.

As also shown in FIG. 9, any unreacted metal film 64 (shown in FIG. 8) can then be stripped after completion of the RTA.

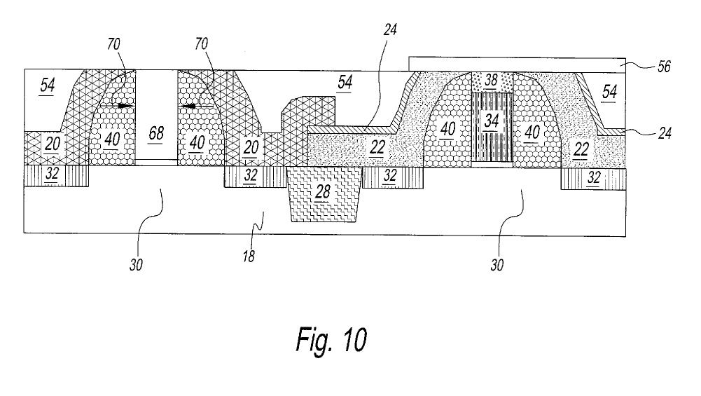

In some embodiments, integrated circuit 10 can be exposed to a full silicization step as shown in FIG. 10. Here, polysilicon layer 34 can be fully silicidized (FUSI) to define a fully silicidized layer 68. Fully silicidized layer 68 has a decreased volume as compared to polysilicon layer 34. Again, the reduction in volume of polysilicon layer 34 to fully silicidized layer 68 pulls nitride layer 20 inward, which induces further compressive stress 70 on channel region 30 of PFET 12 through spacers 40. In addition, FUSI gate has less dopant depletion problem as seen on regular poly silicon gate transistor. The reduction of dopant depletion further improves transistor performance, such as speed.

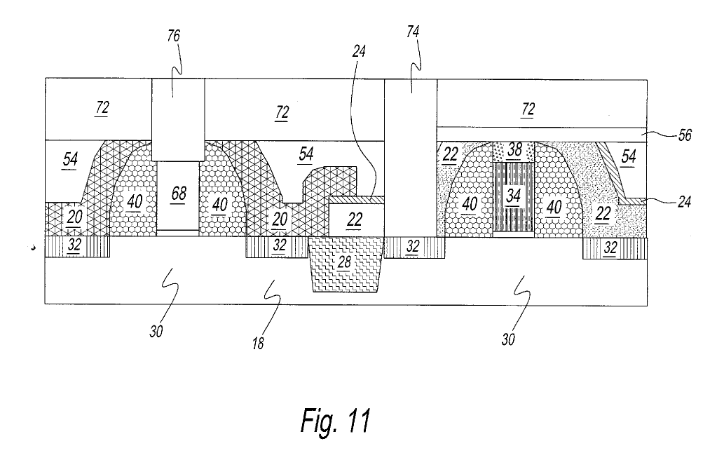

FIG. 11 illustrates integrated circuit 10 after addition of an inter-dielectric layer (ILD) 72, a first contact 74, and a second contact 76 to complete the integrated circuit.

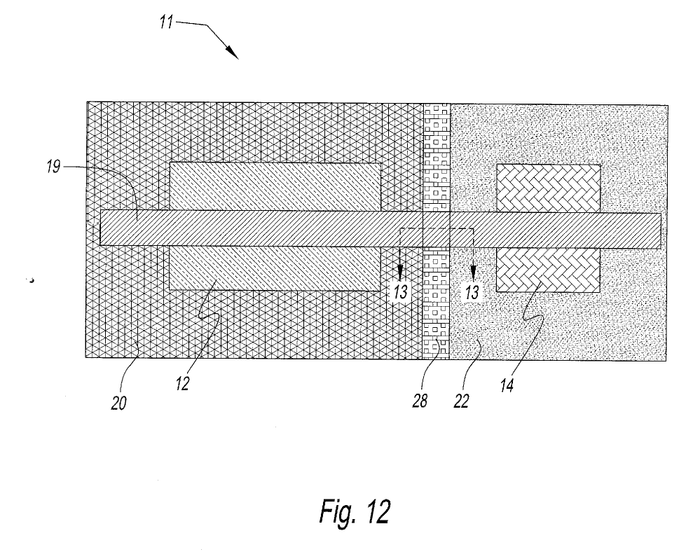

FIG. 12 illustrates a horizontal circuit 11. Horizontal circuit 11 is similar to integrated circuit 10, except that PFET 10 and NFET 12 are connected in a horizontal, not a vertical fashion, and that both PFET 10 and NFET 12 share a common gate 19.

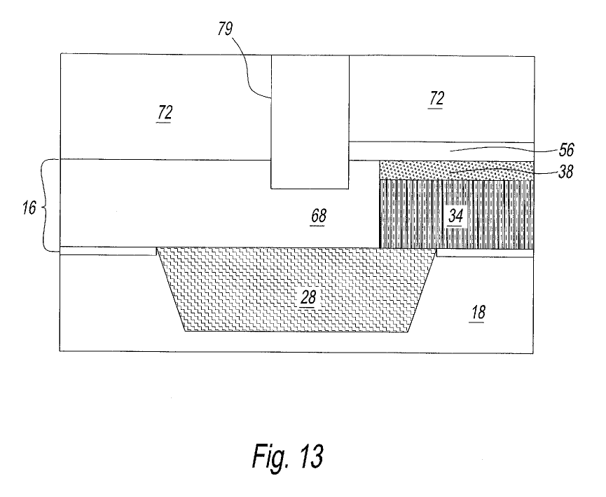

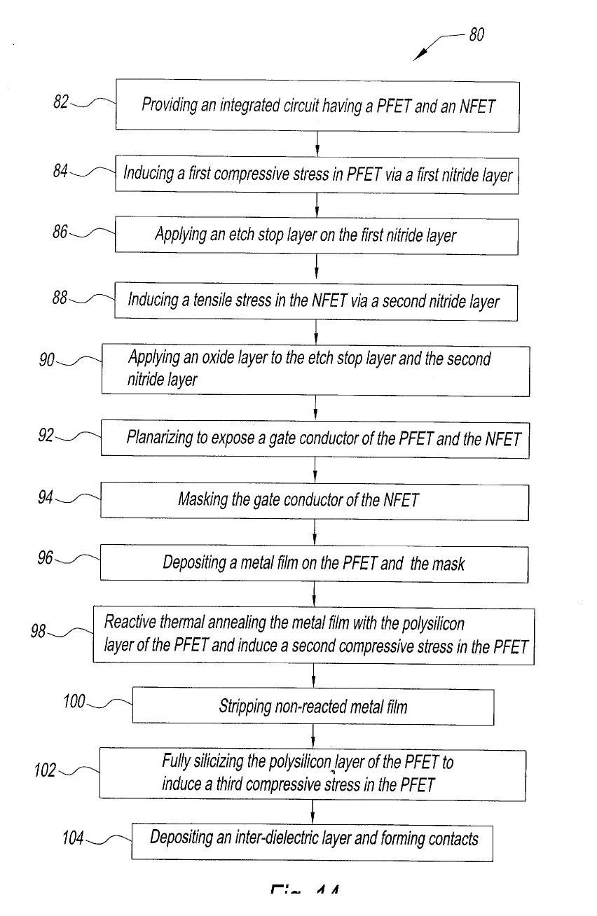

FIG. 13, illustrates a sideways cut 12-12 in FIG. 12. Mask 56 has edge 58 that terminates off-center from STI 28 so that a contact 80 lands on a thick region of silicide 68 on top of common gate 19.

Turning now to FIG. 14, a method according to the present invention of making integrated circuit 10 is generally referred to by reference numeral 80.

Method 80 commences with providing integrated circuit 10 having PFET 12 and NFET 14 during step 82.

A first compressive stress 50 is induced in PFET 12 via a first nitride layer 20 during step 84 and etch stop layer 24 is applied to the first nitride layer during step 86. A photo resist mask 56 is applied and patterned so that NFET region 14 is exposed. Compressive nitride 20 over Nfet region 14 is then etched. Next, a tensile stress 52 is induced in NFET 14 via a second nitride layer 22 during step 88. Similarly, tensile nitride 22 is removed from PFET region 12.

Advantageously, method 80 also induces a second compressive stress 66 on PFET 12. Specifically, method 80 applies an oxide layer 54 to the etch stop layer 24 and the second nitride layer 22 during step 90 and planarizes these layers in step 92. Next, method 80 masks the planarized gate conductor 16 of NFET 14, while leaving the planarized gate conductor 17 of PFET 12 exposed during step 94.

Method 80 then deposits metal film 64 on the exposed PFET gate conductor 16 and the mask in step 96 and reactive thermally anneals the metal film with the polysilicon layer of the exposed PFET gate conductor 16 to induce the second compressive stress in the PFET during step 98.

In some embodiments of method 80, the method includes a stripping step 100 where any non-reacted metal film can be stripped from the integrated circuit.

In other embodiments of method 80, the method can be further used to induce yet a third compressive stress in PFET 12. Here, method 80 can fully silicizing the polysilicon layer of the PFET 12 during step 102 to induce a third compressive stress in the PFET.

Once the desired stress has been induced in integrated circuit 10, method 10 depositing an inter-dielectric layer and forms contacts during step 104.

While the present invention has been described with reference to certain preferred embodiments thereof, those skilled in the art will understand the many modifications and enhancements which can be made without departing from the true scope and spirit of the invention, which is limited only by the appended claims.

What is claimed is:

1. An integrated circuit comprising:
a substrate;
a p-type field effect transistor connected to said substrate;
a compressive nitride layer inducing a first compressive stress in a channel region of said p-type field effect transistor;
an n-type field effect transistor coupled to said substrate;
a tensile nitride layer inducing a tensile stress in a channel region of said n-type field effect transistor; and
a mask defined over an exposed gate conductor of said n-type field effect transistor.

2. The integrated circuit of claim 1, wherein said p-type field effect transistor comprises a gate conductor having a metal silicide layer, said metal silicide layer having a volume sufficient to induce a second compressive stress in said channel region of said p-type field effect transistor.

3. The integrated circuit of claim 2, wherein said second compressive stress is between about 1.0 to 1.5 GPa.

4. The integrated circuit of claim 2, wherein said n-type field effect transistor comprises a gate conductor having a metal silicide layer, said metal silicide layer of said p-type field effect transistor having a greater volume than said metal silicide layer of said n-type field effect transistor.

5. The integrated circuit of claim 1, further comprising a shallow trench isolation region defined in said substrate between said p-type and n-type field effect transistors.

6. The integrated circuit of claim 5, wherein said mask comprises an edge that terminates off-center from a plane defined through an edge of said shallow trench isolation region.

7. The integrated circuit of claim 1, further comprising an etch stop layer on said tensile nitride layer.

8. The integrated circuit of claim 7, wherein said compressive nitride layer overlaps a portion of said etch stop layer to define an overlap region.

9. The integrated circuit of claim 7, wherein said etch stop layer comprises Si₃N₄.

10. An integrated circuit comprising:
a substrate having a source region and a drain region;
a p-type field effect transistor having a gate conductor disposed on said substrate, said gate conductor including a gate dielectric on said substrate, a polysilicon layer on said gate dielectric, and a metal silicide layer on said polysilicon layer;
a channel region under said gate conductor between said source and drain regions;
first and second spacers defined adjacent said gate conductor; and
a compressive nitride layer defined over said gate conductor and said first and second spacers, said compressive nitride layer inducing a first compressive stress in said channel region via said first and second spacers, wherein said metal silicide layer has a volume sufficient to induce a second compressive stress in said channel region via said first and second spacers.

11. The integrated circuit of claim 10, further comprising
an n-type field effect transistor disposed on said substrate; and
a shallow trench isolation region defined in said substrate between said p-type and n-type field effect transistors.

12. The integrated circuit of claim 11, wherein said n-type field effect transistor further comprises a gate dielectric on said substrate, a polysilicon layer on said gate dielectric, and a metal silicide layer on said polysilicon layer.

13. The integrated circuit of claim 12, wherein said metal silicide layer of said n-type field effect transistor has a lower volume than said volume of said metal silicide layer of said p-type field effect transistor.

14. The integrated circuit of claim 10, wherein said second compressive stress is between about 1.0 to 1.5 GPa.

15. A method of manufacturing an integrated circuit, comprising:
laying a tensile stress nitride layer over an NFET to induce a tensile stress on said NFET;
laying a compressive stress nitride layer over a PFET to induce a first compressive stress on said PFET;
removing at least part of said tensile and compressive nitride layers to expose a gate conductor of said NFET and said PFET;
applying a mask over said gate conductor of said NFET; and
inducing a second compressive stress on said PFET.

16. The method of claim 15, wherein inducing said second compressive stress comprises:
depositing a metal film on said PFET and said mask; and
reacting at least a portion of said metal film with a metal silicide layer and a polysilicon layer of said PFET so that said polysilicon layer decreases in volume and said metal silicide layer increases in volume.

17. The method of claim 16, further comprising stripping an unreacted portion of said metal film.

18. The method of claim 16, further comprising inducing a third compressive stress on said PFET by fully silicizing said polysilicon layer.

19. The method of claim 18, wherein said polysilicon layer has a non fully-silicided polysilicon layer that comprises a first metal and a fully silicided polysilicon layer comprises a second metal element.

20. The method of claim 19, wherein said first metal element comprises CoSi and said second metal element comprises NiSi.
